(19) United States
(12) Patent Application Publication
(10) Pub. No.: US 2026/0144032 A1
(43) Pub. Date: May 21, 2026

(54) POWER MESH

(71) Applicant: Taiwan Semiconductor Manufacturing Company, Ltd., Hsinchu (TW)

(72) Inventors: Hui-Wen LI, Hsinchu (TW); Wan-Jiun LIAO, Taichung City (TW); Ze-Xian LU, Hsinchu (TW); Chia-En HUANG, Hsinchu (TW); Jung-Hsuan CHEN, Hsinchu (TW); Ting-Wei CHIANG, New Taipei City (TW)

(21) Appl. No.: 18/949,816

(22) Filed: Nov. 15, 2024

(51) Int. Cl. H01L 23/48; H01L 21/8234; H01L 21/8238; H01L 23/528; H01L 27/088

(52) U.S. Cl. CPC H10W 20/20; H10D 84/0158; H10D 84/0186; H10D 84/038; H10D 84/834; H10W 20/427

(57) ABSTRACT

In accordance with some disclosed embodiments, an IC device includes a first power rail, a second power rail, and a third power rail. A plurality of active regions extend over the substrate and a plurality of conductive contacts extend over the first active region and the second active region. A first via is connected to the first conductive contact and the third power rail. A second via is connected to the second conductive contact and the third power rail. A first portion of the first conductive contact on the second side of the third power rail is electrically disconnected from the first via, and a second portion of the second conductive contact on the first side of the third power rail is electrically disconnected from the second via.

### BACKGROUND

For the operation of integrated circuits (IC), power is supplied and distributed among the various devices of the IC, including appropriate distribution of operation voltages VDD and VSS. The semiconductor industry continues to improve the integration density of various electronic components (e.g., transistors, diodes, resistors, capacitors, etc.) by continual reductions in minimum feature size, which allow more components to be integrated into a given area. As IC performance and design complexity increases, power requirements and complexity also increase. Complex power distribution schemes, such as power mesh arrangements where operation voltages VDD and VSS are distributed by power structures that form a mesh are sometimes employed to distribute power and other signals to these components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a schematic diagram conceptually illustrating an IC device including a power mesh in accordance with disclosed embodiments.

FIG. 2A is a top view illustrating an example of the IC device shown in FIG. 1 in accordance with disclosed embodiments.

FIG. 2B is a first cross-sectional view of the IC device shown in of FIG. 2A in accordance with disclosed embodiments.

FIG. 2C illustrates a second cross-sectional view of the IC device shown in FIG. 2A in accordance with disclosed embodiments.

FIG. 3 illustrates an alternative second cross-sectional view of the IC device shown in FIG. 2A.

FIG. 4 illustrates an alternative second cross-sectional view of the IC device shown in FIG. 2A in accordance with disclosed embodiments.

FIG. 5 is a bottom view illustrating an example back side of the IC device shown in FIG. 2A in accordance with disclosed embodiments.

FIG. 6 is a first cross-sectional view of the IC device shown in FIG. 2A and FIG. 5 in accordance with disclosed embodiments.

FIG. 7 is an alternative first cross-sectional view of the IC device shown in FIG. 2A and FIG. 5 in accordance with disclosed embodiments.

FIG. 8 illustrates a second cross-sectional view of the IC device shown in FIG. 2A and FIG. 5 in accordance with disclosed embodiments.

FIG. 9 is a top view illustrating an example of another IC device in accordance with disclosed embodiments.

FIG. 10 is a bottom view illustrating an example back side of the IC device shown in FIG. 9 in accordance with disclosed embodiments.

FIG. 11 is a block diagram illustrating an IC device in accordance with disclosed embodiments.

FIG. 12 is a flow diagram illustrating an example method for forming an IC including a power mesh in accordance with disclosed embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As the design of an integrated circuit (IC) is becoming more and more complicated, power distribution to devices of the IC also become more complex. Embodiments of the present disclosure are directed power mesh structures that include “staggered” vias to optimize current flow and address IR issues.

Appropriate power supply (e.g. VSS and VDD) and distribution is required for operation of integrated circuit (IC) devices. Various power distribution schemes are employed for distributing such operation voltages VDD and VSS throughout an IC device. A power mesh refers to a network of power supply lines and reference lines placed across an IC to provide a stable and efficient distribution of power to various components and subsystems within the circuit. The power mesh is designed to minimize voltage drops, reduce noise, and maintain a consistent power delivery across the circuit.

Attempts to save chip space by reducing the size (pitch) of power meshes can create IR issues for middle-end and back-end metal routing, particularly where vias and power lines are reduced. Such small power structures can create a resistance bottleneck. To address this challenge, there are various approaches including adjusting the size, thickness, or material resistance using knobs. Additionally, the power mesh plays a crucial role in chip speed, and a superior power IR mesh can enhance overall chip performance.

Device designs can attempt to address these issues by adjusting the size, thickness, or material resistance. Other designs may increase the size of the vias to decrease the resistance. These approaches may result in less flexibility in chip layout due to the increased area of the components. In addition, a dense power mesh is sometimes used for minimizing IR drop. This can result in an increase of power pad sizes, in turn increasing chip area and production costs.

Some disclosed embodiments provide power mesh structures that enhance internal and external IR, provide CPP reduction, and employ parallel power rails that help with process uniformity. Further, flexible layout placement is facilitated with increased power via size, promoting power efficiency. For instance, the number of power vias may be increased, which can lower IR and provide a more robust power rail process. For instance, disclosed examples increase the number of via connections to power rails and use cut metal structures for desired connections to the power rails.

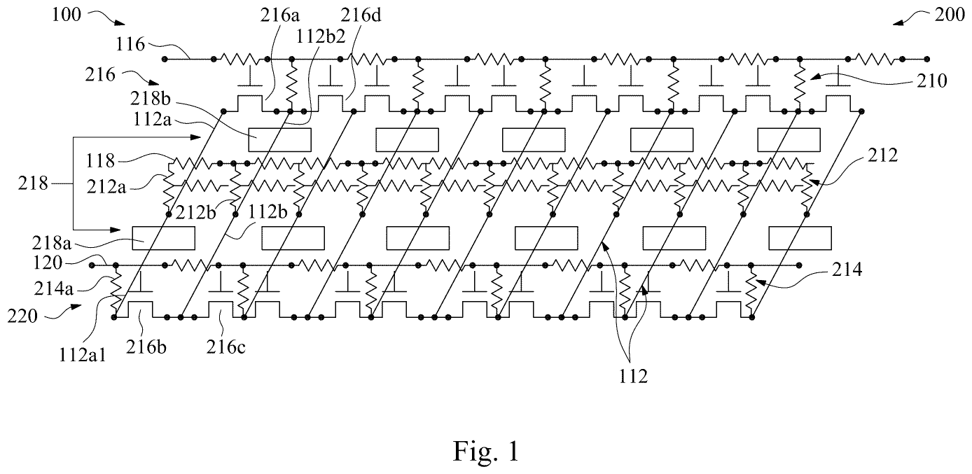

FIG. 1 conceptually illustrates an integrated circuit (IC) device in accordance with disclosed embodiments. The device 100 includes a power mesh 200. In FIG. 1, various electrical connectors are shown as resistors to represent the resistance of the connecting lines. A first power rail 116 (e.g. a VDD power rail) couples to source/drain (S/D) regions a first plurality of transistors 216 through a plurality of vias 210. As used herein, source/drain region(s) may refer to a source or a drain, individually or collectively dependent upon the context.

A second power rail 120 (e.g., another VDD power rail) couples to S/D regions of a second plurality of transistors 220 through a plurality of vias 214. A third power rail 118 (e.g., a VSS or ground rail) is situated between the first power rail 116 and the second power rail 120. The third power rail 118 couples to S/D regions of the first plurality of transistors 216 and the second plurality of transistors through a plurality of vias 212.

As will be discussed further below, conductive contact regions forming the S/D regions (e.g. metal over diffusion (MD) regions) include separating or interrupt structures 218 that selectively electrically disconnected predetermined S/D regions of the first plurality of transistors 216 and the second plurality of transistors 220 from predetermined ones of the vias 210, 212 and/or 214.

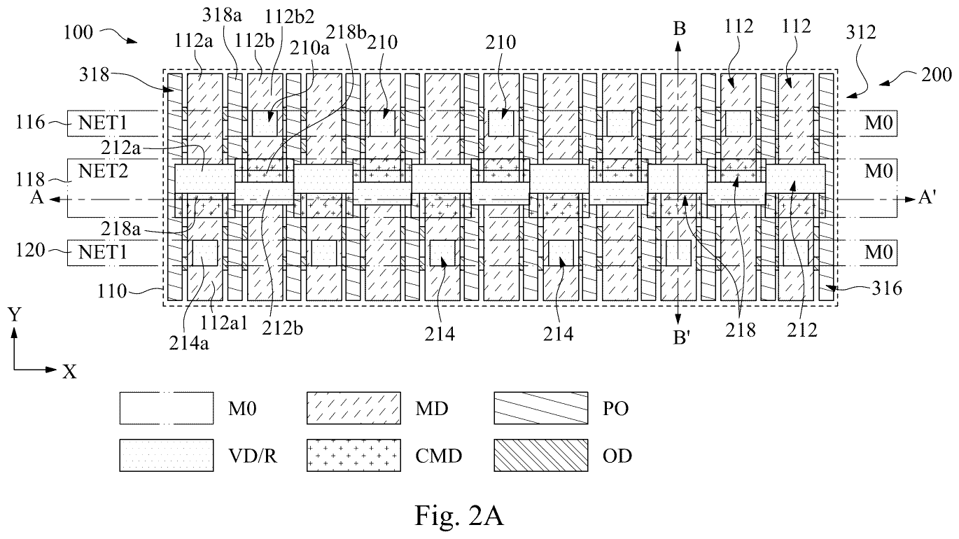

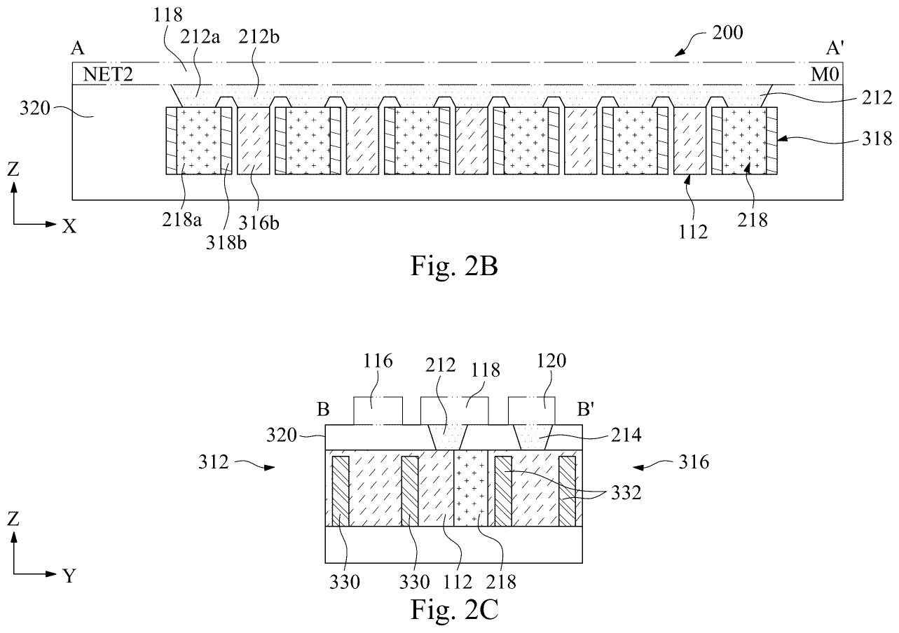

FIG. 2A is a top view illustrating an example layout of the device 100, including the power mesh 200, in accordance with disclosed embodiments. In this embodiment, the device 100 includes a substrate 110, which may include silicon or another semiconductor material. The first power rail 116, the second power rail 120, and the third power rail 118 extend over the substrate parallel to one another in an X direction (e.g. horizontal). The third power rail 118 is situated between the first power rail 116 and the second power rail 120 in a Y direction that crosses (e.g., vertical or perpendicular) the X direction. The power rails 116, 118, 120 may be formed in a first metal layer MO.

A plurality of active areas or regions extend over the substrate 110 in the X direction. For example, the active regions include a first active region 312 on a first side of (e.g. above) the third power rail 118 and a second active region 316 on a second side of (e.g. below) the third power rail 118. The active regions 312, 316 form the channel through which the current flows in the transistor. In this disclosure, the active area may sometimes be referred to as an oxide diffusion (OD) region, where OD region layout patterns are usable to form the S/D regions of the transistors. As discussed further below, the active regions 312, 316 may include planar structures, vertical (i.e. FinFET) structures, stacked nanosheet structures, etc.

A plurality of conductive contacts 112 extend over the substrate 110 in the Y direction and are situated over or around the first active regions 312 and the second active region 316 to form the S/D regions or contacts. The conductive contacts 112 may be formed of metal and sometimes be referred to as metal over diffusion (MD) regions.

A plurality of gate structures 318 extend over the substrate 110 in the Y direction above the first active region and the second active region. The gate structures may be made of a conductive material, such as doped polysilicon (i.e. “poly” or “PO”) or metal. The gate structures 318 are used to control the flow of current in the transistors. The gate structures extend over and/or around the active areas. The plurality of gate structures 318 may further include an oxide placed between the active areas 312 and 316 and the poly.

A plurality of vias 210, 212, 214 connect the conductive contacts 112 to the first, second and third power rails 116, 118, 120 in accordance with disclosed embodiments. With some known power mesh structures, the third power rail (i.e. VSS) is connected to first S/D contacts of the transistors with vias that extend between the VSS power rail and alternating, or every-other conductive contact (i.e. MD region). The second S/D contacts are connected to the first or second power rail (i.e. VDD) with vias extending between the remaining conductive contacts and the first or second VDD power rail. In other words, a first one of the conductive contacts would connect to the VSS rail by a via, and a second one of the conductive contacts adjacent the first conductive contact would connect to the first and second VDD rails by respective vias (but would not be connected to the VSS rail). A third one of the conductive contacts adjacent the second conductive contact would connect to the VSS rail by a respective via, and a fourth one of the conductive contacts adjacent the second conductive contact would connect to the first and second VDD rails by respective vias, and so on. Thus, alternating conductive contacts are connected to the VSS or VDD power rails by respective vias.

In accordance with disclosed embodiments, each of the conductive contacts 112 are connected to the third (VSS) power rail 118 and the first power rail 116 or the second power rail 120 by respective vias. For ease of explanation, a first conductive contact 112a and a second conductive contact 112b of the plurality of conductive contacts will be described, along with a first gate structure 318a of the plurality of gate structures.

Referring to FIG. 1 and FIG. 2A, the first conductive contact 112a is situated on a first side of the first gate structure 318a, and the second conductive contact 112b, which is adjacent the first conductive contact 112a), is situated on a second side of the first gate structure 318a. Thus, the conductive contact 112a, the first gate structure 318a, and the second conductive contact 112b respectively form the first S/D terminal, the gate, and the second S/D terminal of a transistor 216 or 220.

The plurality of vias 212 connect the third power rail 118 to the conductive contacts 112, and the conductive contacts 112 are further connected to the first power rail 116 and second power rail 120 by the vias 210 and 214 in the manner described herein. The vias 210, 212, 214 extend in a third, or Z direction, that crosses (i.e. is perpendicular to) the X and Y directions. A first one of the vias 212a is connected to the first conductive contact 112a and the third power rail 118. A second one of the vias 212b is connected to the second conductive contact 112b and the third power rail 118.

Rather than the conductive contacts 112a and 112b both connecting S/D contacts of one transistor (e.g. transistor 216a or 220a) to the third power rail 118 by the vias 212a and 212b, the conductive contacts 112 are separated into two portions. A first portion 112a1 of the first conductive contact 112 a below the third power rail 118 is electrically disconnected from the first via 212a, and a second portion 112b2 of the second conductive contact 112b above the third power rail 118 is electrically disconnected from the second via 212b.

In some embodiments, the conductive contacts 112 (i.e. MD regions) are separated or cut to provide cut MD regions (CMD) 218. As such, the via 212a connects the third power rail 118 to the conductive contact 112a (i.e. one S/D of the transistor 216a, see FIG. 1), but the via 212a and thus the third power rail 118 is not connected to either S/D of the transistor 216b due to the CMD 218a. Similarly, the via 212b connects the third power rail 118 to the conductive contact 112b (i.e. one S/D of the transistor 216c), but the via 212b and thus the third power rail 118 is not connected to either S/D of the transistor 216d due to the CMD 218a.

FIG. 2B shows a horizontal (i.e. X direction) cross-sectional view of the device 100 taken along line A-A′. As shown in FIG. 2B, each of the plurality of vias 214 extend through a dielectric or insulating material 320 and are connected together in this embodiment. A via of the first plurality of vias 210 is formed over every other conductive contacts of the one or more conductive contacts 112. The third plurality of vias 214 are formed over every other conductive contact of the one or more conductive contacts 112 that are opposite from the first plurality of vias 210. The second plurality of vias 214 are formed over each the conductive contacts 112, though the CMDs 218 disconnect certain ones of the vias 212 (and thus the third power rail 118) from respective conductive contacts 112. Since the plurality of vias 214 are connected together, resistance is reduced between the third power rail 118 and the conductive contacts 112.

FIG. 2C illustrates a vertical (Y direction) cross-sectional view of the device 100 taken along line B-B′. The conductive contact 112 is separated into two portions by the CMD 218 such that the illustrated via 212 connects the third power rail 118 to the left side portion of the illustrated conductive contact 112 (i.e. one S/D of the transistor 216a, see FIG. 1), but the via 212 and thus the third power rail 118 is not connected to the right side portion of the illustrated conductive contact 112 due to the CMD 218. In the example of FIG. 2C the active areas 312 and 316 include vertical (i.e. FinFET) structures. The active area 312 includes a plurality of fins 330 extending vertically (i.e. Z direction), and the active area 316 includes fins 332.

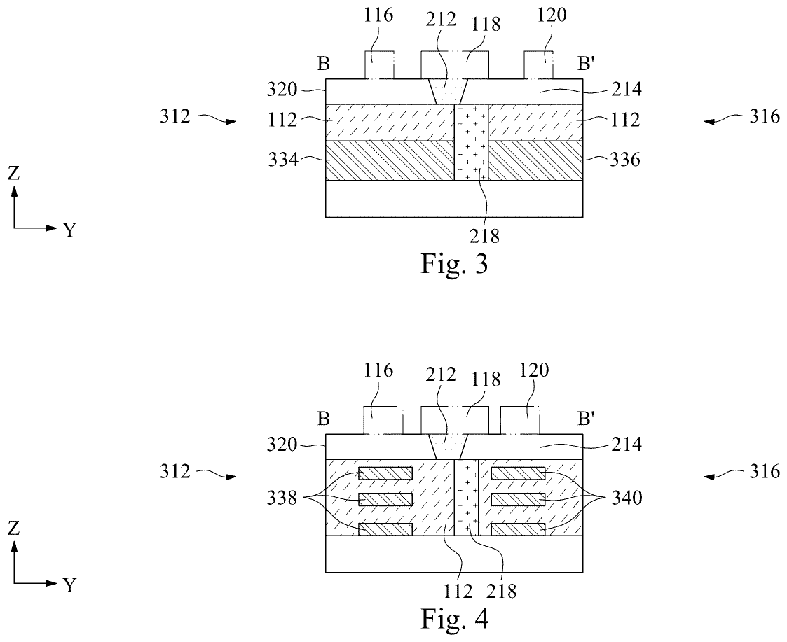

As noted above, other embodiments may employ different active area structures. FIG. 3 illustrates an example of an alternative active area using planar structures. In FIG. 3, the active area 312 includes a planar structure 334 and the active area 316 includes a planar structure 336. FIG. 4 illustrates another example of an alternative active area using nanosheet structures. In FIG. 4, the active area 312 includes stacked nanosheets 338 and the active area 316 includes stacked nanosheets 340.

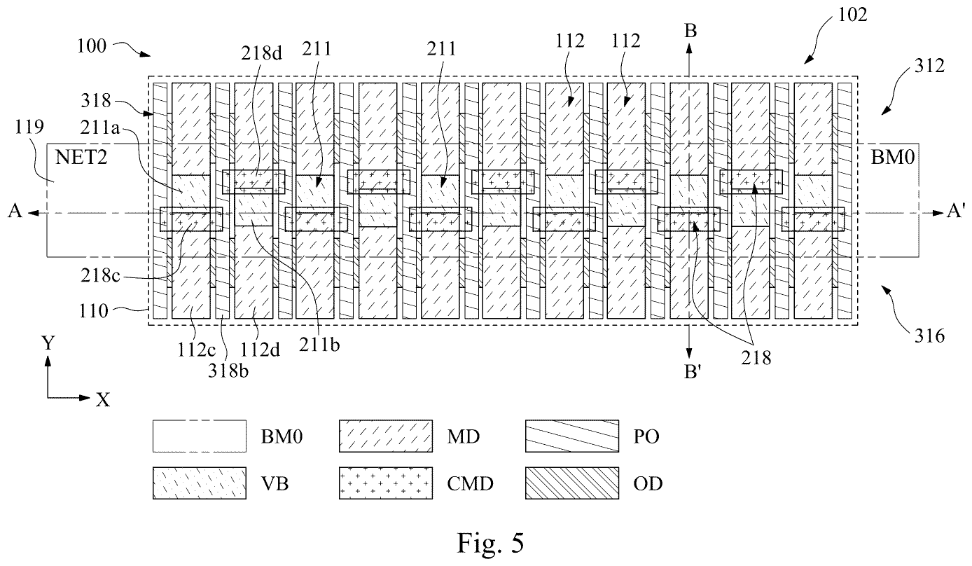

FIG. 5 illustrates an embodiment where an additional power rail is provided on a back side 102 of the device 100. The semiconductor industry continues to improve the integration density of various electronic components (e.g., transistors, diodes, resistors, capacitors, etc.) by continual reductions in minimum feature size, which allow more components to be integrated into a given area. To increase power distribution capabilities, certain dual-side power rail devices may be employed. With such dual-side power rail devices, the power mesh 200 includes front-side and back-side interconnect structures, wherein area and resistance benefits may be realized.

In FIG. 2A, the top side of the device 100 is shown. FIG. 5 shows an example of a backside 102 of the device 100. The backside 102 includes additional aspects of the power mesh 200, including a fourth power rail 119, which may be another VSS power rail. The power rail 119 may be provided in a backside first metal layer BM0. The backside 102 power mesh is similar to the front side structure shown in FIG. 2A, where each of the conductive contacts 112 are connected to the fourth power rail 119 by respective backside vias 211. As with the front side shown in FIG. 2A, cut metal structures 218 separate portions of the conductive contacts 112 from the fourth power rail 119.

One of the conductive contacts 112c is situated on a first side of the gate structure 318b, and another conductive contact 112d, which is adjacent the conductive contact 112c, is situated on a second side of the gate structure 318b. The plurality of backside vias 211, which extend in the Z-direction, connect the fourth power rail 119 to the conductive contacts 112. A first one of the backside vias 211a is connected to the conductive contact 112c and the fourth power rail 119. A second one of the backside vias 211b is connected to the conductive contact 112d and the fourth power rail 119.

The bottom portion of the conductive contact 112c below the fourth power rail 119 is electrically disconnected from the first backside via 211a by the CMD 218c, and the upper portion of the conductive contact 112d above the fourth power rail 119 is electrically disconnected from the second backside via 211b by the CMD 218d.

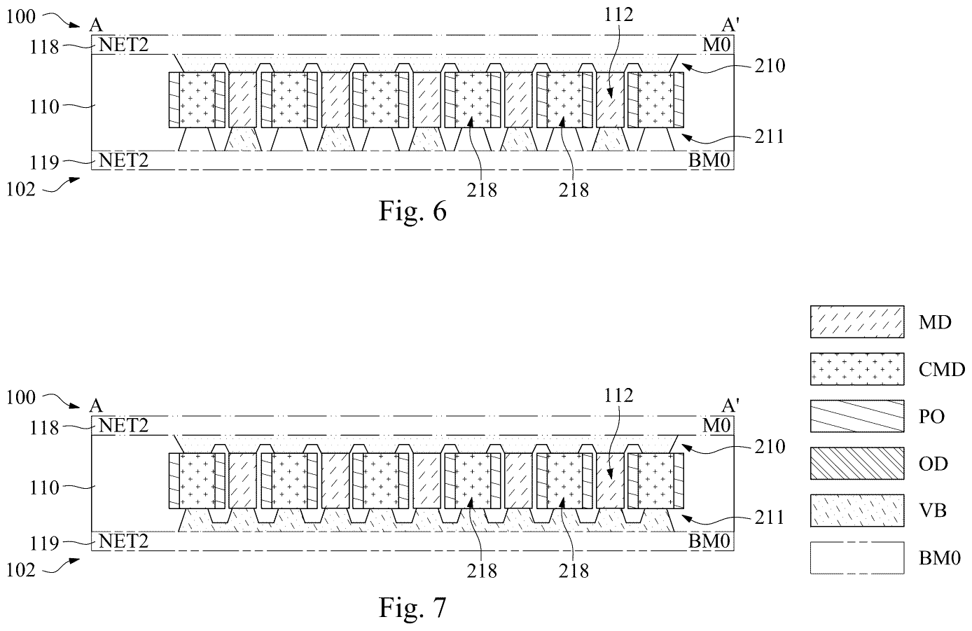

FIG. 6 is a side view taken along line A-A′ in FIG. 5. FIG. 6 illustrates aspects of the backside 102 of the device 100, including aspects of the power mesh 200. In the example of FIG. 6, the backside vias 211 each extend in the Z direction and are discreet or separated from one another in the X direction. As noted previously, the vias 210 that connect the third power rail 212 to the conductive contacts 112 are connected in the X direction in some examples. FIG. 7 illustrates and alternative example of the backside 102 power mesh 200, where the backside vias 211 that connect the fourth power rail 119 to the conductive contacts 112 are connected in the X direction.

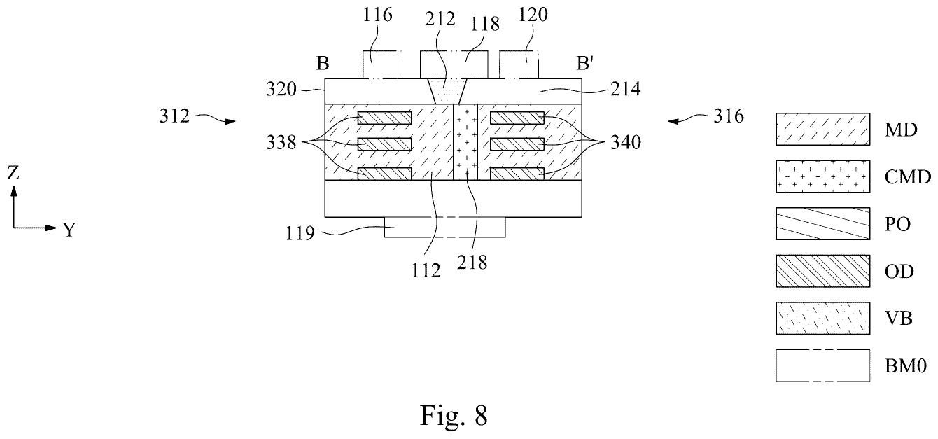

FIG. 8 is a view taken along line B-B′ of FIG. 5, in which the active areas 312 and 316 include nanosheet structures 338 and 340 in accordance with the embodiment shown in FIG. 4. Other examples using a backside power mesh 200 may employ other active area structures, such as the vertical (FinFET) structures shown in FIG. 2C or the planar structures shown in FIG. 3.

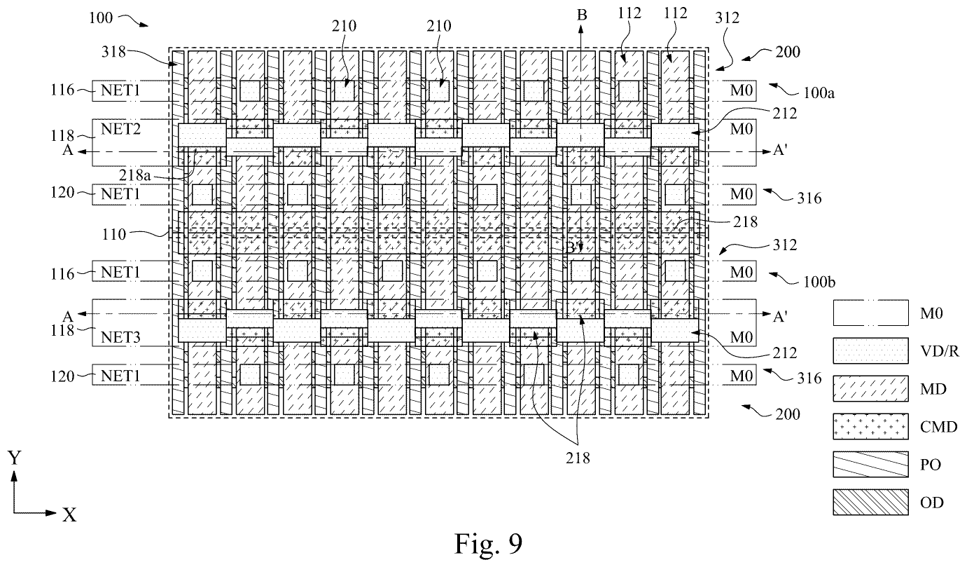

FIG. 9 illustrates another example, where the device 100 includes two of the power mesh circuits 200 distributing power to two of the devices shown in FIG. 2A. In FIG. 5, the device 100 includes an upper device 100a and a lower device 100b. The upper device 100a is separated from the lower device 100b by a cut metal structure 218 in which the conductive contacts 112 of the upper device 100a are separated from the conductive contacts 112 of the lower device 100b. In the example of FIG. 9, the lower device 100b, and more particularly the vias 212 and adjacent cut metal structures 218 are mirror images of the corresponding structures of the upper device 100a.

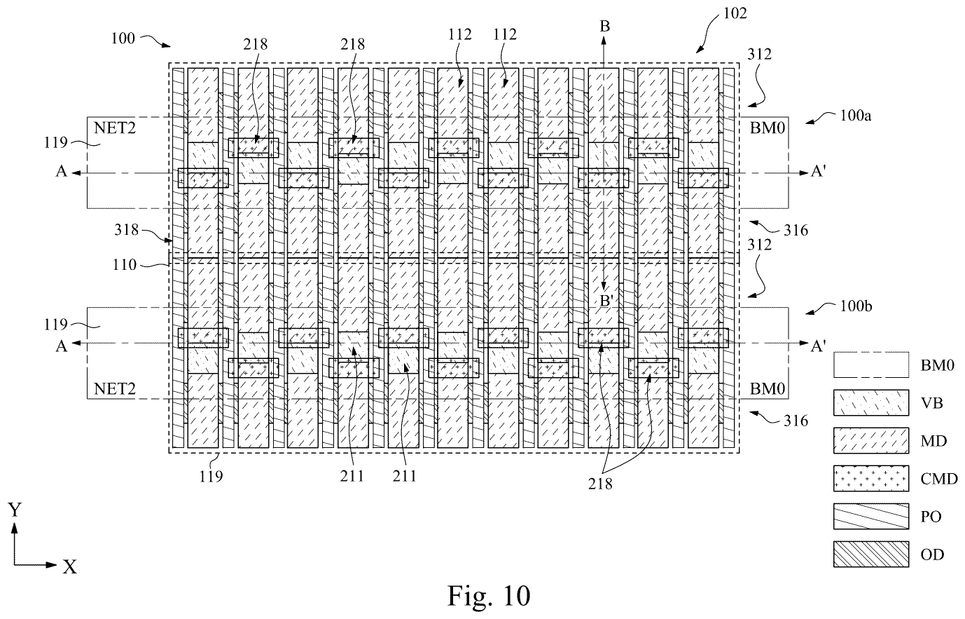

FIG. 10 illustrates a backside 102 of the device 100 shown in FIG. 9 for an embodiment having a backside power mesh 200. As with the backside 102 shown in FIG. 5, backside vias 211 connect the conductive contacts 112 to the backside power rails. In FIG. 10, the backside power mesh includes a fifth power rail 119a, in addition to the fourth power rail 119. In some implementations, both backside power rails 119 and 119a are VSS power rails, though other examples could configure one or more backside rails as VDD power rails.

As with the example of FIG. 5, the conductive contacts 112 are connected to the fifth power rail 119a by respective backside vias 211. As with the front side shown in FIG. 2A, cut metal structures 218 separate portions of the conductive contacts 112 from the fifth power rail 119a. The backside vias 211 and adjacent cut metal structures 218 of the lower device 100b are arranged as mirror images of those of the upper device 100a.

Among other things, power mesh structures disclosed herein may provide improved IR power distribution structures. The examples shown in FIG. 9 and FIG. 10 illustrate two devices provided on a single substrate 110. In various IC devices, additional devices and circuits may be divided in respective areas of the device.

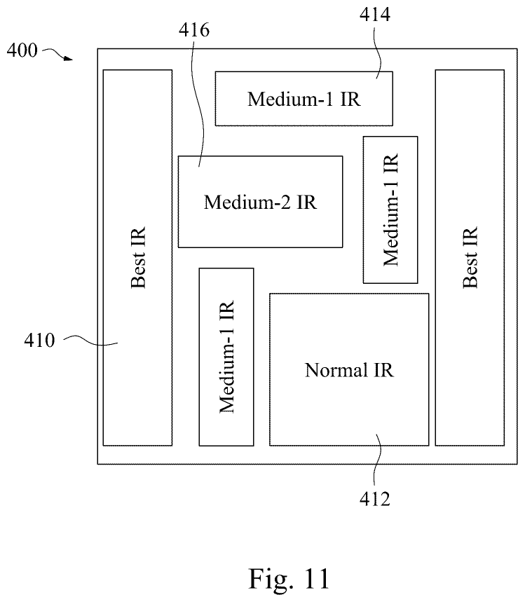

The power mesh 200 is structured to address issues such as voltage drop, noise or interference, and IR issues. Depending on power requirements, different power mesh structures are used for the various circuits and devices in respective areas of the device. FIG. 11 illustrates this concept, where different areas of an IC device 400 use different power mesh structures in different areas of the device 400, depending on IR requirements.

For example, the device 400 includes a power mesh layout 410, a power mesh layout 412, a power mesh layout 414, and a power mesh layout 416. For instance, a power mesh layout including backside power rails may provide increased IR performance, and a backside power mesh arrangement in which the backside vias are connected (FIG. 7) may provide improved IR performance as compared to a backside power mesh arrangement in which the backside vias are discreet (FIG. 6). In this embodiment, the power mesh layout 410 produces the best IR performance. The power mesh layout 412 has normal IR performance. Both the power mesh layout 414 and the power mesh layout 416 have medium IR performance.

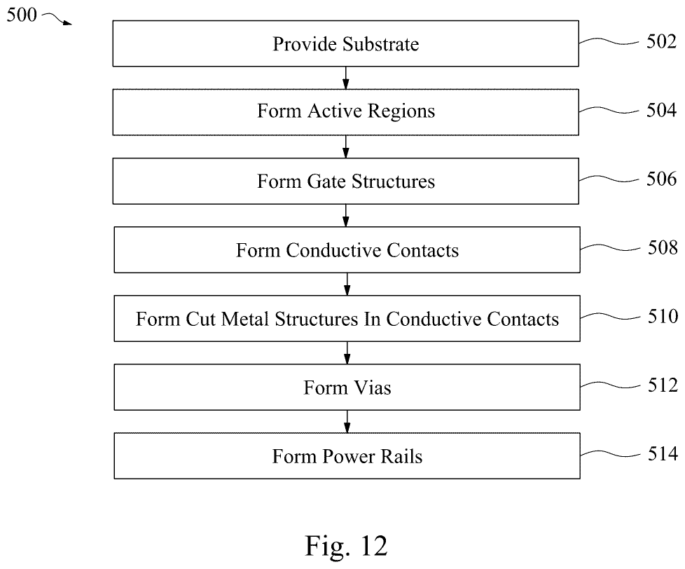

FIG. 12 is a flow diagram illustrating a method 500 for producing a device, such as the device 100 discussed above. Referring to FIG. 11 together with FIG. 2A, the substrate 110 is provided at operation 502. The substrate 110 may be a silicon substrate, though other semiconductor materials are used in alternative implementations, such as germanium or compound semiconductors.

In operation 504, a first active region 312 and a second active region 316 are formed on or over the substrate 110 extending in the first direction (i.e. X direction). In some examples, an epitaxial layer is grown on top of the substrate 110. The active layer or regions 312, 316 are formed by selectively doping regions of the substrate or epitaxial layer to create N-type and P-type regions.

In operation 506, gate structures 318 are formed. The gate structures 318 include a first gate structure that extends in the second direction (i.e. Y direction) over the first active region 312 and the second active region 316. Forming the gate structures 318 may include forming a gate electrode layer made of a conductive material such as doped polysilicon or metal. Additionally, a gate oxide made of high-k dielectric material, like hafnium oxide (HfO2), may be formed to separate the gate electrode from the channel region (i.e. active area).

Conductive contacts are formed in operation 508. The conductive contacts 112 extend in the second, or Y, direction and form source/drain (S/D) contacts. A first one of the conductive contacts 112 is on a first side of the first gate structure 318, and a second one of the conductive contacts 112 is on a second side of the first gate structure 318 opposite first side, the second conductive contact extending in the second direction over the first active area and the second active area to form second S/D contacts.

In operation 510, cut metal regions 218 are formed that separate a first portion of the first and second conductive contacts from a second portion of the first and second conductive contacts 112. In some examples, a line separation pattern CMD (i.e. “cut-MD pattern”) is used to signify a separation step during the semiconductor fabrication process, by which the contiguous conductive contacts extending in the Y direction are segmented into first and second portions as discussed in conjunction with FIGS. 1 and 2A.

In some embodiments, the CMD process includes removing one or more contact portions from the conductive contacts 112. The removed portion of the conductive contact 112 corresponds to a CMD region or structure 218. In some embodiments, the portion of the contact 112 that is removed in operation 510 is identified in layout design by a cut feature pattern. In some embodiments, the cut feature pattern identifies a location of the removed contact.

Such removal processes for forming the CMD structures 218 may include one or more etching processes suitable to remove a portion of the conductive contacts 112. In some embodiments, the etching process includes identifying a portion of the conductive contact 112 that is to be removed, and etching the portion of the conductive contact 112 that is to be removed. In some embodiments, a mask is used to specify portions of the conductive contact 112 that are to be cut or removed. In some embodiments the mask is a hard mask, while in other embodiments, the mask is a soft mask. Etching may include, for example, plasma etching, reactive ion etching, chemical etching, dry etching, wet etching, and other suitable processes or combinations thereof. After removal of the contact portions from the conductive contacts 112, the removed space may be filled by a dielectric material, such as an oxide material, to form the CMD structures 218 that segment the conductive contacts 112 into the first and second portions.

In operation 512, vias are formed that extending in a third direction (i.e. Z direction) that crosses the first direction and the second direction. For instance, a first via 214 is connected to the first portion of the first conductive contact, and a second via is connected to the second portion of the second conductive contact. In some examples, dielectric layers, such as silicon dioxide or silicon nitride, separate the various layers of the device structure and provide electrical isolation. Thus, dielectric layer 320 is provided between the power rails in the MO metal layer and the conductive contacts 112. An opening is formed in the dielectric layer that is filled with a conductive material to vertically connect different layers of the device 100 as described herein. In some examples, a layer of photoresist material is applied to the surface of the dielectric layer. A mask containing the desired via pattern, such as the vias 211 and 212 connected in the horizontal or X direction, is aligned and placed over the photoresist layer. Ultraviolet (UV) light is shone through the mask, exposing the photoresist in the desired via locations. The exposed photoresist is then developed using a developer solution, which removes the desired areas to create the via locations. In other examples, the via areas are selectively etched away using a suitable etchant. The via openings are then filled with a conductive material deposition techniques such as physical vapor deposition (PVD) or chemical vapor deposition (CVD).

First, second and third power rails extending in the first direction are formed in operation 514. In some examples, the first, second and third power rails 116, 118, 120 are formed in a first metal layer (i.e. MO). The front side power rails 116, 118, 120 and other interconnect structures may be formed through any acceptable process, such as a damascene process, a dual damascene process, or the like.

In some embodiments, to form the backside power rail 119, a carrier wafer is bonded to a top surface of device 100. The carrier wafer may be bonded to the top surface by one or more bonding layers. After the carrier wafer is bonded to the front-side of the device 100, the device may be flipped such that the backside 102 of the device 100 faces upwards. A thinning process may be applied to the backside 102 of the substrate 110. The thinning process may comprise a planarization process (e.g., a mechanical grinding, a CMP, or the like), an etch-back process, a combination thereof, or the like. The backside power mesh structures such as the power rails 119 and backside vias 211 are then formed. In the illustrated examples, the backside power rails 119 are formed in a backside metal layer BM0.

The first via 212a electrically connects the third power rail 118 to the first portion of the first conductive contact 112a and the second portion of the first conductive contact 112a is not electrically connected to the third power rail 118 due to the CMD structure 218a. The second via 212b electrically connects the third power rail 118 to the second portion of the second conductive contact 112b and the first portion of the second conductive contact 112b is not electrically connected to the third power rail 118 due to the CMD structure 218b.

In accordance with some disclosed embodiments, an IC device includes a substrate, with a first power rail, a second power rail, and a third power rail extending over the substrate parallel to one another in a first direction. The third power rail is situated between the first power rail and the second power rail in a second direction that crosses the first direction. A plurality of active regions extend over the substrate in the first direction and include a first active region on a first side of the third power rail and a second active region on a second side of the third power rail opposite the first side. A plurality of gate structures extend over the substrate in the second direction. A plurality of conductive contacts extend over the first active region and the second active region in the second direction to form source/drain (S/D) regions. The plurality of conductive contacts include a first conductive contact on a first side of the first gate structure, and a second conductive contact adjacent the first conductive contact on a second side of the first gate structure. A first via extends in a third direction that crosses the first direction and the second direction, and is connected to the first conductive contact and the third power rail. A second via extends in the third direction and is connected to the second conductive contact and the third power rail. A first portion of the first conductive contact on the second side of the third power rail is electrically disconnected from the first via, and a second portion of the second conductive contact on the first side of the third power rail is electrically disconnected from the second via.

In accordance with further disclosed embodiments, an IC device includes a substrate with a first power rail, a second power rail, and a third power rail extending over the substrate parallel to one another in a first direction. The third power rail is situated between the first power rail and the second power rail in a second direction that crosses the first direction. A plurality of active regions extend over the substrate in the first direction. The active regions include a first active region on a first side of the third power rail and a second active region on a second side of the third power rail opposite the first side. A plurality of gate structures extend over the substrate in the second direction and are connected to the first active region and the second active region. A plurality of conductive contacts extend over the substrate in the second direction and are connected to the first active region and the second active region to form source/drain (S/D) regions. The plurality of conductive contacts include a first conductive contact on a first side of the first gate structure, and a second conductive contact adjacent the first conductive contact on a second side of the first gate structure. A first via extends in a third direction that crosses the first direction and the second direction, and is connected to the first conductive contact and the third power rail. A second via extends in the third direction and is connected to the second conductive contact and the third power rail. The first via is connected to the second via in the second direction.

In accordance with still further disclosed embodiments, a method for forming an ID device includes providing a substrate, and forming a first active region and a second active region on or over the substrate extending in a first direction. A first gate structure is formed extending in in a second direction that crosses the first direction over the first active region and the second active region. A first conductive contact is formed on a first side of the first gate structure extending in the second direction over the first active area and the second active area to form first source/drain (S/D) contacts. A second conductive contact is formed on a second side of the first gate structure opposite first side extending in the second direction over the first active area and the second active area to form second S/D contacts. A first cut metal region is formed separating a first portion of the first conductive contact from a second portion of the first conductive contact. A second cut metal region is formed separating a first portion of the second conductive contact from a second portion of the second conductive contact. A first via is formed extending in a third direction that crosses the first direction and the second direction. The first via is connected to the first portion of the first conductive contact. A second via is formed extending in the third direction and is connected to the second portion of the second conductive contact. A first power rail and a second power rail are formed extending in the first direction. A third power rail is formed extending in the first direction between the first power rail and the second power rail. The first via electrically connects the third power rail to the first portion of the first conductive contact and the second portion of the first conductive contact is not electrically connected to the third power rail, and wherein the second via electrically connects the third power rail to the second portion of the second conductive contact and the first portion of the second conductive contact is not electrically connected to the third power rail.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
a substrate;
a first power rail, a second power rail, and a third power rail extending over the substrate parallel to one another in a first direction, wherein the third power rail is situated between the first power rail and the second power rail in a second direction that crosses the first direction;
a plurality of active regions extending over the substrate in the first direction including a first active region on a first side of the third power rail and a second active region on a second side of the third power rail opposite the first side;
a plurality of gate structures extending over the substrate in the second direction, including a first gate structure;
a plurality of conductive contacts extending over the first active region and the second active region in the second direction to form source/drain (S/D) regions, the plurality of conductive contacts including a first conductive contact on a first side of the first gate structure, and a second conductive contact adjacent the first conductive contact on a second side of the first gate structure;
a first via extending in a third direction that crosses the first direction and the second direction, and connected to the first conductive contact and the third power rail;
a second via extending in the third direction connected to the second conductive contact and the third power rail; and
wherein a first portion of the first conductive contact on the second side of the third power rail is electrically disconnected from the first via, and wherein a second portion of the second conductive contact on the first side of the third power rail is electrically disconnected from the second via.

2. The device of claim 1, comprising a third via extending in the third direction connected to the first portion of the first conductive contact and the second power rail.

3. The device of claim 2, comprising a fourth via extending in the third direction connected to the second portion of the second conductive contact and the first power rail.

4. The device of claim 1, wherein the first via is connected to the second via.

5. The device of claim 1, wherein the plurality of active regions are planar structures.

6. The device of claim 1, wherein the plurality of active regions are FinFET structures.

7. The device of claim 1, wherein the second direction is perpendicular to the first direction, and the third direction is perpendicular to the first and second direction.

8. The device of claim 1, wherein the first conductive contact includes a first cut metal structure that separates the first portion of the first conductive contact from the first via, and wherein the second conductive contact includes a second cut metal structure that separates the second portion of the second conductive contact from the second via.

9. The device of claim 1, further comprising:
a fourth power rail situated between the first power rail and the second power rail in the second direction;
a third via extending in the third direction connected to the first conductive contact and the fourth power rail and a fourth via connected to the second conductive contact and the fourth power rail; and
wherein the first portion of the first conductive contact is electrically disconnected from the third via, and wherein the second portion of the second conductive contact is electrically disconnected from the fourth via.

10. The device of claim 9, wherein the third power rail is on a first side of the substrate in the third direction, and the fourth power rail is on a second side of the substrate opposite the first side in the third direction.

11. The device of claim 9, wherein the third via is connected to the fourth via.

12. A device comprising:
a substrate;
a first power rail, a second power rail, and a third power rail extending over the substrate parallel to one another in a first direction, wherein the third power rail is situated between the first power rail and the second power rail in a second direction that crosses the first direction;
a plurality of active regions extending over the substrate in the first direction including a first active region on a first side of the third power rail and a second active region on a second side of the third power rail opposite the first side;
a plurality of gate structures extending over the substrate in the second direction and connected to the first active region and the second active region, including a first gate structure;
a plurality of conductive contacts extending over the substrate in the second direction and connected to the first active region and the second active region to form source/drain (S/D) regions, the plurality of conductive contacts including a first conductive contact on a first side of the first gate structure, and a second conductive contact adjacent the first conductive contact on a second side of the first gate structure;
a first via extending in a third direction that crosses the first direction and the second direction, and connected to the first conductive contact and the third power rail;
a second via extending in the third direction connected to the second conductive contact and the third power rail; and
wherein the first via is connected to the second via in the second direction.

13. The device of claim 12, wherein a first portion of the first conductive contact on the second side of the third power rail is electrically disconnected from the first via, and wherein a second portion of the second conductive contact on the first side of the third power rail is electrically disconnected from the second via.

14. The device of claim 13, wherein the first conductive contact includes a first cut metal structure that separates the first portion of the first conductive contact from the first via, and wherein the second conductive contact includes a second cut metal structure that separates the second portion of the second conductive contact from the second via.

15. The device of claim 13, further comprising:
a third via extending in the third direction connected to the first portion of the first conductive contact and the second power rail; and
a fourth via connected to the second portion of the second conductive contact and the first power rail.

16. The device of claim 12, further comprising:
a fourth power rail situated between the first power rail and the second power rail in the second direction;
a third via extending in the third direction connected to the first conductive contact and the fourth power rail and a fourth via connected to the second conductive contact and the fourth power rail; and
wherein the third via is connected to the fourth via in the second direction.

17. The device of claim 16, wherein a first portion of the first conductive contact is electrically disconnected from the third via, and wherein a second portion of the second conductive contact is electrically disconnected from the fourth via.

18. A method, comprising:
providing a substrate;
forming a first active region on or over the substrate extending in a first direction;
forming a second active region on or over the substrate extending in the first direction;
forming a first gate structure extending in a second direction that crosses the first direction over the first active region and the second active region;
forming a first conductive contact on a first side of the first gate structure, the first conductive contact extending in the second direction over the first active region and the second active region to form first source/drain (S/D) contacts;
forming a second conductive contact on a second side of the first gate structure opposite first side, the second conductive contact extending in the second direction over the first active region and the second active region to form second S/D contacts;
forming a first cut metal region separating a first portion of the first conductive contact from a second portion of the first conductive contact;
forming a second cut metal region separating a first portion of the second conductive contact from a second portion of the second conductive contact;
forming a first via extending in a third direction that crosses the first direction and the second direction, and connected to the first portion of the first conductive contact;
forming a second via extending in the third direction connected to the second portion of the second conductive contact;
forming a first power rail extending in the first direction;
forming a second power rail extending in the first direction;
forming a third power rail extending in the first direction between the first power rail and the second power rail; and
wherein the first via electrically connects the third power rail to the first portion of the first conductive contact and the second portion of the first conductive contact is not electrically connected to the third power rail, and wherein the second via electrically connects the third power rail to the second portion of the second conductive contact and the first portion of the second conductive contact is not electrically connected to the third power rail.

19. The method of claim 18, further comprising:
forming a third via extending in the third direction connected to the second portion of the first conductive contact forming a fourth via extending in the third direction connected to the first portion of the second conductive contact; and
wherein the third via electrically connects the second power rail to the first portion second of the first conductive contact, and wherein the second via electrically connects the first power rail to the first portion of the second conductive contact.

20. The method of claim 18, further comprising:
forming the first via and the second via such that the first via is connected to the second via in the first direction.
